(19) United States
(12) Patent Application Publication
(10) Pub. No.: US 2009/0278562 A1
(43) Pub. Date: Nov. 12, 2009

(54) Test Device and Test Method for Semiconductor Device

(75) Inventor: Hiroshi Zaitsu, Hayami-Gun (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/436,986

(22) Filed: May 7, 2009

(30) Foreign Application Priority Data
May 7, 2008 (JP) 2008-120902

(51) Int. Cl. G01R 31/26

(52) U.S. Cl. 324/765

(57) ABSTRACT

The objective of this invention is to provide a test device that can perform a variety of function tests with a relatively simple constitution. The test device is for testing semiconductor device 1, which contains input terminal IN, output terminal OUT and control terminal CTRL, and whose output terminal is in the high-impedance state corresponding to the control signal applied to control terminal CTRL. The test device comprises test signal supply circuit 20, comparator 30 that compares the output signal from the output terminal with a reference voltage, reference voltage setting part 40 that sets the reference voltage to the voltage on the high-level side or on the low-level side, and load voltage supply circuit 50 that applies the load voltage to the output signal when the control signal is input. Said load voltage supply circuit 50 applies a load voltage greater than the voltage on the high-level side when the reference voltage is set to the high-level side, and it applies a load voltage less than the voltage on the low-level side when the reference voltage is set to the low-level side.

### FIELD OF THE INVENTION

The present invention pertains to a test device and a test method for performing function tests of a semiconductor device whose output can assume a high-impedance state.

### BACKGROUND OF THE INVENTION

Typically, before semiconductor devices are shipped from the manufacturer, they undergo a series of tests to eliminate defective or malfunctioning semiconductor devices. One such test is a function test for checking whether the functions of the semiconductor device operate as designed. For example, a function test may be performed as follows: the semiconductor device to be tested is attached to the test board of the test device, a test signal is applied to the input terminal of the semiconductor device, and it is determined whether the signal appearing at the output terminal is the expected signal. Patent Reference 1 pertains to a test device that performs function tests on the semiconductor devices, and it discloses a method for performing the function tests at high speed and with high precision.

### [Patent Reference 1] Japanese Kokai Patent Application No. 2003-270299

The test device for performing the function tests uses a comparator that compares the signal appearing at the output terminal of a semiconductor device with a reference voltage, and determines whether the expectation value signal output from the comparator is the signal listed in a truth table. For example, when the truth table shown in FIG. 7 is used, if the level (H or L) of the expectation value signal output from the comparator and the level (H or L) of the test signal agree with the values in the truth table, it is determined that the function is normal.

However, said test device has the following problems. It has only one comparator, and only one reference voltage is used with the comparator. Consequently, it can execute only limited function tests. As a result, the specifications of the function test must be relaxed, which is undesirable. Of course, if a plurality of comparators is used, it is possible to perform a plurality of function tests. However, the cost rises correspondingly, and testing becomes complicated.

For example, if the reference voltage of the comparator is set to 1.35 V and the signal appearing at the output terminal of the device being tested is greater than 1.35 V, a high-level expectation value signal is output from the comparator, but it will be impossible to determine whether the output of the device being tested exceeds the nominal voltage. Similarly, if the signal appearing at the output terminal of the device being tested is less than 1.35 V, a low-level expectation value signal is output from the comparator, but it will be impossible to determine whether the output of the device being tested is less than the nominal voltage. In addition, for a tri-state buffer, etc., that operates such that the output of the semiconductor device is high impedance (HIZ), it is impossible to evaluate the high-impedance state.

The purpose of the present invention is to solve the aforementioned problems of the prior art by providing a test device and a test method that can perform a variety of function tests with a relatively simple constitution.

### SUMMARY OF THE INVENTION

The present invention provides a test device characterized by the following facts: the test device is for testing a semiconductor device that contains an input terminal, an output terminal and a control terminal, and whose output terminal can assume a high-impedance state on a basis of the control signal applied to the control terminal; the test device comprises a supply circuit that supplies a test signal to said input terminal, a comparator that compares the output signal output from said output terminal in response to said test signal with a reference voltage, and outputs a high-level or low-level expectation value signal, a reference voltage setting part that sets said reference voltage to the high-level side voltage or low-level side voltage, and a load voltage supply circuit that applies a load voltage to said output signal; said load voltage supply circuit operates such that when said reference voltage is set to the high-level side voltage, a load voltage above said high-level side voltage is applied to said output signal, and when said reference voltage is set to the low-level side voltage, a load voltage below said low-level side voltage is applied to said output signal.

Preferably, when said control signal is applied, said reference voltage setting part sets the reference voltage to the low-level side with respect to a high-level test signal, and sets the reference voltage to the high-level side with respect to a low-level test signal. Also, the following is preferred: said load voltage supply circuit contains a switch that is turned on or off in response to said control signal, and when said control signal is applied, said switch is turned on, so that the load voltage is applied to said output signal.

The load voltage supply circuit may supply a load current to the input terminal or the output terminal of the semiconductor device. The test device may also contain a determination circuit that judges whether the expectation value signal output from the comparator and the test signal agree with the truth table.

The present invention provides a test method characterized by the following facts: the test method is for testing a semiconductor device that contains an input terminal, an output terminal and a control terminal, and whose output terminal can assume a high-impedance state on the basis of a control signal applied to the control terminal; the test method comprises the following steps: a step in which a test signal is applied to said input terminal, and said control signal is applied to said control terminal; a step in which the load voltage is applied to the output signal at said output terminal; a step in which the output signal with said applied load voltage is compared with a reference voltage; and a step in which it is determined whether the function is normal on the basis of the expectation value signal as the comparison result and the test signal; wherein when said test signal is at the high level, said reference voltage is set to the voltage on the low-level side, and when said test signal is at the low level, said reference voltage is set to the voltage on the high-level side; and wherein said load voltage is greater than the voltage on the high-level side when said reference voltage is at the high-level side, and said load voltage is less than said voltage on the low-level side when said reference voltage is at the low-level side.

In a preferred test method, said method also comprises the following steps: a step in which the test signal is applied to said input terminal; a step in which the output signal at said output terminal and the reference voltage are compared; and a step in which it is determined whether the function is normal on the basis of the expectation value signal as the comparison result and the test signal.

The present invention also provides a test method characterized by the following facts: the test method is for testing a semiconductor device that contains an input terminal, an output terminal and a control terminal, and whose output terminal can assume a high-impedance state on the basis of a control signal applied to the control terminal; the test method comprises the following steps: a first step in which the following operation is performed: when the reference voltage of the comparator is at the first level, the test signal is applied to said input terminal and the output signal appearing at said output terminal is compared with the first-level reference voltage, and while the test signal is applied to said input terminal, the control signal is applied to said control terminal, the first load voltage is applied to said output signal, the output signal with said applied first load voltage is compared with the first-level reference voltage, and a first function test is performed; and a second step in which the following operation is performed: when the reference voltage of the comparator is at the second level, the test signal is applied to said input terminal, the output signal at said output terminal is compared with the second-level reference voltage, and while the test signal is applied to said input terminal, the control signal is applied to said control terminal, the second load voltage is applied to said output signal, the output signal with said applied second load voltage is compared with the second-level reference voltage, and a second function test is performed; wherein either said first step or said second step can be executed first; and wherein when the first level of the reference voltage is above the second level, the first load voltage is higher than the first level of the reference voltage, and the second load voltage is less than the second level of the reference voltage.

### BRIEF DESCRIPTION OF THE DRAWINGS

FIG. 1 is a block diagram illustrating the constitution of the test device pertaining to an embodiment of the present invention.

FIG. 2 is a diagram illustrating an example of the semiconductor device as the object to be measured.

FIG. 3 is a diagram illustrating a preferred circuit constitution of the test device of the present embodiment.

FIG. 4(a) is a diagram illustrating the relationship between the DATA as well as the control signal and the reference voltage as well as the load voltage. FIG. 4(b) is a diagram illustrating the truth table for the logic circuit of the semiconductor device.

FIG. 5 is a flow chart illustrating the operation of the test device in the embodiment.

FIG. 6 is a diagram illustrating effect of the test device in the embodiment.

FIG. 7 is a diagram illustrating the truth table of the function test in the prior art.

### REFERENCE NUMERALS AND SYMBOLS AS SHOWN IN THE DRAWINGS

In the figures, 10 represents a test device, 20 a test signal supply circuit, 22, a voltage level generator, 30, a comparator, 40, a reference voltage setting part, 50, a load voltage supply circuit, 60, a determination circuit, DRV, PIV, LOAD, switches

### DESCRIPTION OF THE EMBODIMENTS

According to the present invention, plural reference voltages of the comparator are set, and the load voltage is applied to the output signal under prescribed conditions. As a result, it is possible to execute efficiently a variety of function tests including a test for the high-impedance state. In addition, by setting plural reference voltages, it is possible to determine whether the output signal is within a prescribed voltage range. Moreover, if the test device contains a load voltage supply circuit, there is no need to add additional circuitry, so that the rise in the cost of the device can be suppressed.

A preferred embodiment of the present invention will be explained below in more detail with reference to the figures.

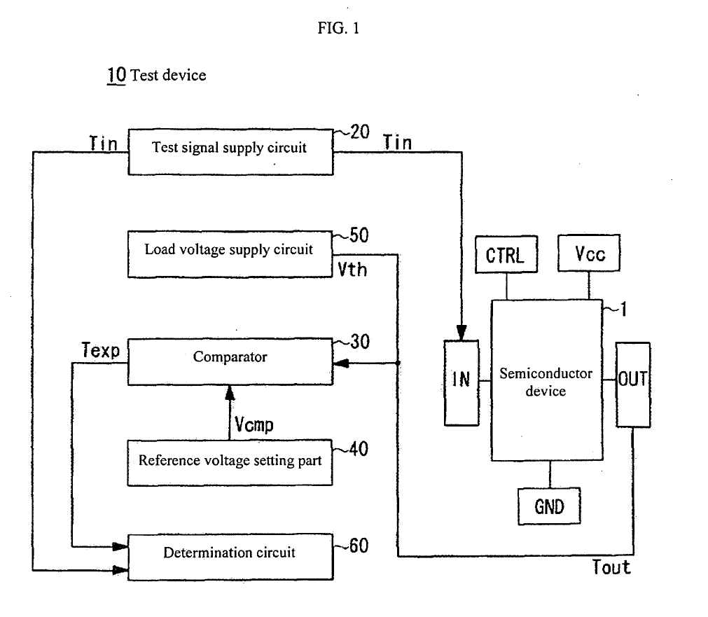

FIG. 1 is a block diagram schematically illustrating the test device in an embodiment of the present invention. In this embodiment, semiconductor device 1 as the object to be measured contains input terminal IN, output terminal OUT, control terminal CTRL, power supply terminal Vcc, and ground terminal GND. Depending on whether a high-level or a low-level signal is input to input terminal IN, a high-level or a low-level signal is output from output terminal OUT. Said control terminal CTRL controls the operation of semiconductor device 1 in accordance with the high level or low level of the applied control signal. For example, when the control signal is at the high level, input terminal IN and output terminal OUT are electrically connected to each other via an internal logic circuit, and the signal is output from output terminal OUT corresponding to the logic formula of the logic circuit. On the other hand, when the control signal is at the low level, said input terminal IN and output terminal OUT are separated from each other, and said output terminal OUT assumes the high-impedance state irrespective of the level of the signal at the input terminal.

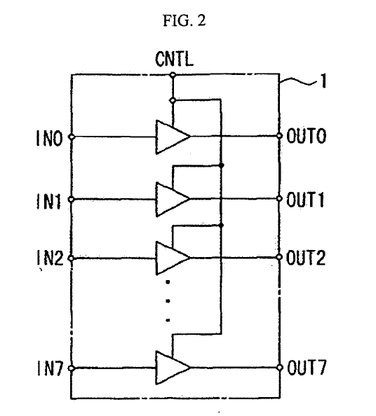

FIG. 2 is a diagram illustrating an example of the constitution of the semiconductor device. It contains input terminals IN0-IN7, output terminals OUT0-OUT7, control terminal CTRL, and an 8-bit driver. In the following explanation, it is assumed that when control terminal CTRL is at the high level, a normal logic operation is performed, where an output signal at the high level is output for an input signal at the high level, and an output signal at the low level is output for an input signal at the low level, and that when control terminal CTRL is at the low level, the output terminal assume the high-impedance state irrespective of whether the input signal is high level or low level.

Test device 10 contains the following circuits: test signal supply circuit 20 that supplies test signal Tin to input terminal IN of semiconductor device 1; comparator 30 that compares output signal Tout appearing at output terminal OUT of semiconductor device 1 with reference voltage Vcmp and outputs expectation value signal Texp; reference voltage setting part 40 that sets reference voltage Vcmp of comparator 30 to the voltage on the high-level side or the low-level side; load voltage supply circuit 50 that applies load voltage Vth to output signal Tout when the control signal is at the low level, that is, when semiconductor device 1 is in the high-impedance state; and determination circuit 60 that determines whether test signal Tin and expectation value signal Texp output from comparator 30 agree with the truth table values. Also, although they are not shown in the figure, test device 10 contains a memory, which stores the program for executing the function test and the required data therefor, and a controller that controls the various parts according to the program.

Said test signal supply circuit 20 applies test signal Tin at the high level or low level or a prescribed voltage to input terminal IN according to the test sequence. The voltage of test signal Tin is selected appropriately corresponding to the power source voltage or the driving voltage or the like of the semiconductor device as the object to be measured.

Output signal Tout appearing at output terminal OUT is input to one input of said comparator 30, and reference voltage Vcmp is input to the other input, so that the two signals can be compared. If output signal Tout is greater than reference voltage Vcmp, expectation value signal Texp at the high level is output, and if output signal Tout is less than reference voltage Vcmp, expectation value signal Texp at the low level is output.

Said reference voltage setting part 40 sets reference voltage Vcmp to the high-level side or the low-level side voltage. As will be explained further below, said reference voltage Vcmp is switched appropriately corresponding to the control signal applied to control terminal CTRL and the state of the function test. For example, the switching and the voltage value of reference voltage Vcmp may be set by the program for executing the function test.

For load voltage supply circuit 50, when the control signal is at the high level, that is, when the semiconductor device performs a normal logic operation, preferably, load voltage Vth is not applied to output signal Tout. On the other hand, if the control signal is at the low level, that is, when output terminal OUT is in the high-impedance state, load voltage Vth is applied to output signal Tout. Said fed load voltage Vth is switched appropriately corresponding to the voltage of test signal Tin, etc. Load voltage Vth on the high-level side is greater than reference voltage Vcmp on the high-level side, and when output terminal OUT is in the high-impedance state, output signal Tout is approximately equal to load voltage Vth on the high-level side. As a result, expectation value signal Texp as the output of comparator 30 will be at the high level.

Also, load voltage Vth on the low-level side is set to be less than reference voltage Vcmp on the low-level side, and when output terminal OUT is in the high-impedance state, output signal Tout is approximately equal to load voltage Vth on the low-level side. As a result, expectation value signal Texp as the output of comparator 30 will be at the low level. The switching and the voltage value of said load voltage Vth, for example, can be set by the program for executing the function test.

Said determination circuit 60 determines that the function is normal if expectation value signal Texp output from comparator 30 and test signal Tin agree with the truth table values, and it determines that the function is abnormal if said signals do not agree with the truth table values.

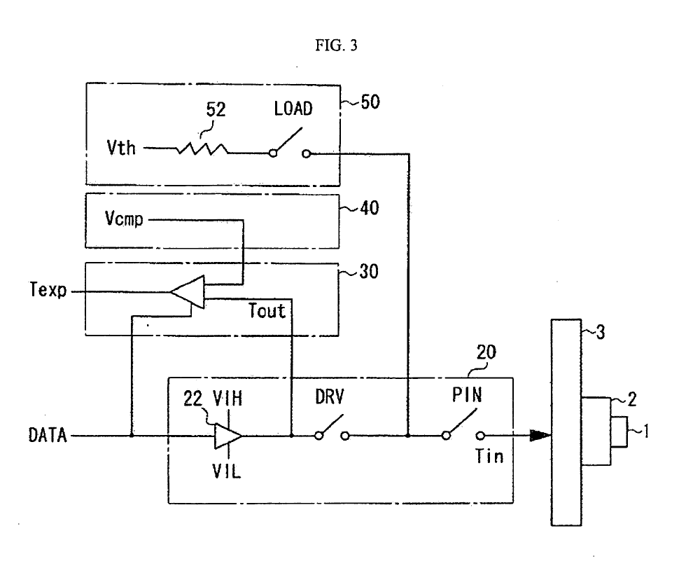

FIG. 3 is a diagram illustrating a preferred circuit constitution of the test device shown in FIG. 1. Said semiconductor device 1 is attached via socket 2 on test board 3. Said test signal supply circuit 20 comprises voltage level generator 22 that generates a voltage signal with a level VIH (high) or VIL (low) corresponding to whether DATA is at the high level or low level, switch DRV connected in series with voltage level generator 22, and switch PIN connected in series with switch DRV. For example, the voltage level VIH is 2.0 V, and the voltage level VIL is 0.5 V. However, the specific voltage levels can be changed appropriately corresponding to the object to be measured and the contents of the function test. Said switch DRV and switch PIN are turned on when test signal Tin is applied to input terminal IN. Consequently, when DATA is at the high level, test signal Tin at level VIH is supplied, and when DATA is at the low level, test signal Tin at level VIL is supplied.

One of the inputs to comparator 30 is connected to the connection mode between voltage level generator 22 and switch DRV, and the other input is connected to reference voltage Vcmp. When output signal Tout is evaluated, because switch DRV and switch PIN are turned on, output signal Tout is applied to one input of the comparator. Said comparator 30 outputs expectation value signal Texp, which is the result of comparing output signal Tout with reference voltage Vcmp.

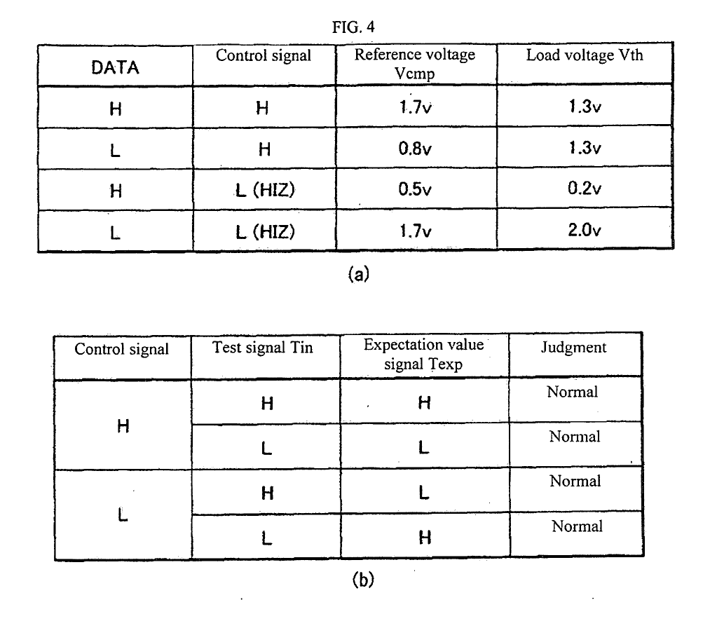

Said reference voltage setting part 40 sets the voltage value of reference voltage Vcmp, described above. FIG. 4(a) shows an example of the setting of the reference voltage Vcmp. As shown in the figure, reference voltage Vcmp can be set to any of four values corresponding to the control signal and the level of DATA. Here, when the control signal is at the high level, depending on the level of DATA, reference voltage Vcmp may be set to 1.7 V (on the high-level side) or 0.8 V (on the low-level side). Also, when the control signal is at the low level, that is, when the semiconductor device is in the high-impedance state, depending on the level of the DATA, reference voltage Vcmp is set to 1.7 V (on the high-level side) or 0.5 V (on the low-level side).

Said load voltage supply circuit 50 contains a voltage source that supplies load voltage Vth, resistor 52 (e.g., 1 kΩ), and switch LOAD connected in series with resistor 52. It is preferred that load voltage supply circuit 50 be used for supplying the load current to the input/output terminal of the semiconductor device. In a typical test device, load voltage supply circuit 50 is included in test board 3. The load voltage supply circuit is included in test board 3 if it is not otherwise supplied.

Switch LOAD is turned on to supply load voltage Vth to output signal Tout when the control signal is at the low level, that is, when output terminal OUT is in the high-impedance state. As shown in FIG. 4(a), when reference voltage Vcmp is on the low-level side, said load voltage Vth is set below said reference voltage by 0.2 V (that is, on the low-level side), and when reference voltage Vcmp is on the high-level side, the load voltage is set 2.0 V above the reference voltage (that is, on the high-level side). In addition, one may also adopt a scheme in which switch LOAD is turned on when output signal Tout has been determined to be a normal logical output and excludes the high-impedance state. In this case, load voltage Vth is set to (VOH+VOL)/2, where VOH represents the high-level of output signal Tout and VOL the low level of the output signal, and load current can flow. For example, in this case, Vth is set to about 1.3 V. The circuit shown in FIG. 3 shares the input terminal and output terminal of semiconductor device 1, that is, when the input terminal is connected, test signal supply circuit 20 is turned on, and when the output terminal is connected, comparator 30, reference voltage setting part 40, and load voltage supply circuit 50 are turned on.

Said determination circuit 60 receives expectation value signal Texp and test signal Tin, and determines whether these signals agree with the values in the truth table shown in FIG. 4(b).

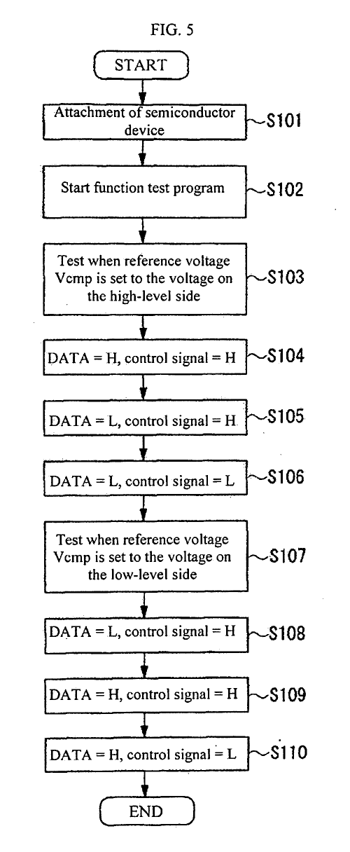

The specific operation of the test device will now be explained with reference to the flow chart shown in FIG. 5. Here, the semiconductor device as the object to be measured is attached to test board 3 (step S101), and the program of the function test is started (step S102).

Initially, the function test in which reference voltage Vcmp is set to the high-level side (1.7 V) is performed (step S103). DATA is set to the high level, the control signal is set to the high level (step S104), and test signal Tin at level DIH (2.0 V) is supplied via switch DRV and switch PIN to input terminals IN0-IN7.

Corresponding to the application of test signal Tin, output signal Tout is output from output terminals OUT0-OUT7, and output signal Tout is applied to one input to comparator 30. When the control signal is at the high level, switch LOAD is turned off, so that load voltage Vth is not applied to output signal Tout. As shown in FIG. 4(a), reference voltage Vcmp, which is input to the other input of comparator 30, is set to 1.7 V. If output signal Tout is greater than 1.7 V, expectation value signal Texp output from comparator 30 goes to the high level. On the other hand, if it is less than this value, expectation value signal Texp goes to the low level. Said determination circuit 60 determines that the state is normal if test signal Tin and expectation value signal Texp agree with the values in the truth table shown in FIG. 4(b).

Then, DATA is set to the low level, the control signal is set to the high level (step S105), and test signal Tin at level DIL (0.5 V) is applied, and, as described above, output signal Tout and reference voltage Vcmp are compared in comparator 30, and expectation value signal Texp is output. If output signal Tout is less than 1.7 V, expectation value signal Texp goes to the low level, and it is determined that the function is normal.

Then, DATA is set to the low level, and the control signal is set to the low level (step S106). Test signal Tin at level DIL is applied to input terminals IN0-IN7. In this case, load voltage Vth is set to 2.0 V, and it is applied to output signal Tout. If output terminal OUT is in the high-impedance state, output signal Tout will be about 2.0 V. If the output terminal is in the high-impedance state, output signal Tout is greater than reference voltage Vcmp, and expectation value signal Texp goes to the high level. Said determination circuit 60 determines whether expectation value signal Texp and test signal Tin agree with the values in the truth table. In this case, test signal Tin is at level DIL of 0.5 V. However, it may be a signal less than 0.5 V, e.g., level DIL may be 0.2 V.

Then, the function test in which the reference voltage is set to the voltage at the high-level side is executed (step S107). DATA is set to the low level, and the control signal is set to the high level (step S108). Test signal Tin at level DIL (0.5 V) is applied to the input terminal, and, correspondingly, output signal Tout is applied to one input of comparator 30. In this case, reference voltage Vcmp is set to 0.8 V on the low-level side. If the function is normal, expectation value signal Texp from comparator 30 will go to the low level, to be in agreement with the value in the truth table.

Then, DATA is set to the high level, and the control signal is set to the high level (step S109). Test signal Tin at level DIH (2.0 V) is applied to the input terminal, and, correspondingly, output signal Tout is fed to one input to comparator 30. If the function is normal, expectation value signal Texp from comparator 30 will go to the high level, to be in agreement with the value in the truth table.

Then, DATA is set to the high level, and the control signal is set to the low level (step S110). In this case, reference voltage Vcmp is set to 0.5 V on the low-level side. Also, load voltage Vth is set to 0.2 V on the low-level side. If the function is normal, the output terminal will assume the high-impedance state and output signal Tout will be at 0.2 V, approximately equal to load voltage Vth. Consequently, expectation value signal Texp output from comparator 30 goes to the low level, which accords with the values in the truth table.

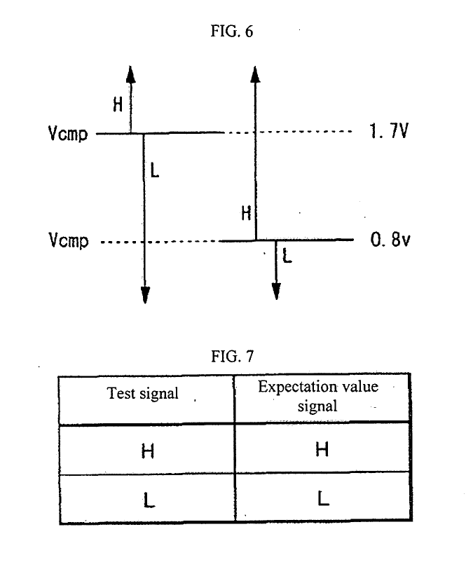

In this way, by setting reference voltage Vcmp to the voltage on the high-level side or the low-level side and performing a function test, it is possible to check that output signal Tout exceeds or falls below the prescribed voltage. As shown in FIG. 6, when reference voltage Vcmp is set to 1.7 V, if expectation value signal Texp is at the high level, output signal Tout is found to be higher than 1.7 V. Then, in the next function test, when reference voltage Vcmp is set to 0.8 V, if expectation value signal Texp is at the high level, output signal Tout is found to be 0.8 V or higher. Similarly, when reference voltage Vcmp is set to 1.7 V, if expectation value signal Texp is at the low level, output signal Tout is found to be 1.7 V or lower. In the next function test, when reference voltage Vcmp is set to 0.8 V, if expectation value signal Texp is at the low level, output signal Tout is found to be 0.8 V or lower.

In addition, when the high-impedance state function test is performed, if load voltage Vth is less than reference voltage Vcmp and it is not in the high-impedance state, test signal Tin that will produce high output signal Tout is applied. On the other hand, if load voltage Vth is greater than reference voltage Vcmp and it is not in the high-impedance state, test signal Tin that will produce low output signal Tout is applied, so that it is possible to obtain expectation value signal Texp with its level inverted with respect to the level of test signal Tin, and it is possible to evaluate the high-impedance state. In this way, according to this embodiment, only one comparator is required to execute various types of function tests at high efficiency.

The values of reference voltage Vcmp in the foregoing are merely examples, and the values of Vcmp can be changed appropriately corresponding to the specifications of the semiconductor device under test. Also, the test sequence shown in FIG. 5 is merely an example and does not restrict the present invention. For example, one may also adopt a scheme in which the semiconductor device is first tested for normal operation of logic functions, and then the high-impedance test is performed.

A preferred embodiment of the present invention was explained in detail above. However, the present invention is not limited to this particular embodiment. As long as the essence of the invention as described in the claims is observed, various modifications and changes may be made.

1. A test device for testing a semiconductor device that contains an input terminal, an output terminal and a control terminal, and whose output terminal can assume a high-impedance state on the basis of a control signal applied to the control terminal, characterized in that the test device comprises
a supply circuit that supplies a test signal to said input terminal,
a comparator that compares the output signal output from said output terminal in response to said test signal with a reference voltage, and outputs a high-level or low-level expectation value signal,
a reference voltage setting part that sets said reference voltage to the high-level side voltage or low-level side voltage,
and a load voltage supply circuit that applies a load voltage to said output signal;
wherein said load voltage supply circuit operates such that when said reference voltage is set to the high-level side voltage, a load voltage above said high-level side voltage is applied to said output signal, and when said reference voltage is set to the low-level side voltage, a load voltage below said low-level side voltage is applied to said output signal.

2. The test device of claim 1 characterized in that when said control signal is applied, said reference voltage setting part sets the reference voltage to the low-level side with respect to a high-level test signal, and sets the reference voltage to the high-level side with respect to a low-level test signal.

3. The test device of claim 1 characterized in that said load voltage supply circuit contains a switch that is turned on or off in response to said control signal, so that when said control signal is applied, said switch is turned on, and the load voltage is applied to said output signal.

4. The test device of claim 1 characterized in that the load voltage supply circuit has the function of supplying the load current to the input terminal or output terminal of the semiconductor device.

5. The test device of claim 1 characterized in that the test device also contains a determination circuit that determines whether the expectation value signal output from the comparator and the test signal agree with values in a truth table.

6. A test method for testing a semiconductor device that contains an input terminal, an output terminal and a control terminal, and whose output terminal can assume a high-impedance state on the basis of a control signal applied to the control terminal, characterized in that the test method comprises the following steps:
a step in which a test signal is applied to said input terminal, and said control signal is applied to said control terminal;
a step in which the load voltage is applied to the output signal at said output terminal;
a step in which the output signal with said applied load voltage is compared with a reference voltage;
and a step in which it is determined whether the function is normal on the basis of the expectation value signal as the comparison result and the test signal;
wherein when said test signal is at the high level, said reference voltage is set to the low-level side voltage, and when said test signal is at the low level, said reference voltage is set to the high-level side voltage; and wherein said load voltage is above the high-level side voltage when said reference voltage is at the high-level side voltage, and said load voltage is below said low-level side voltage when said reference voltage is at the low-level side voltage.

7. The test method of claim 6 characterized in that said method also comprises the following steps:
a step in which the test signal is applied to said input terminal;
a step in which the output signal at said output terminal and the reference voltage are compared;
and a step in which it is determined whether the function is normal on the basis of the expectation value signal as the comparison result and the test signal.

8. A test method for testing a semiconductor device that contains an input terminal, an output terminal and a control terminal, and whose output terminal can assume a high-impedance state on the basis of a control signal applied to the control terminal, characterized in that the test method comprises the following steps:
a first step in which the following operation is performed: when the reference voltage of the comparator is at the first level, the test signal is applied to said input terminal and the output signal at said output terminal is compared with the first-level reference voltage, and while the test signal is applied to said input terminal, the control signal is applied to said control terminal, the first load voltage is applied to said output signal, the output signal with said applied first load voltage is compared with the first-level reference voltage, and a first function test is performed;
and a second step in which the following operation is performed: when the reference voltage of the comparator is at the second level, the test signal is applied to said input terminal, the output signal at said output terminal is compared with the second-level reference voltage, and while the test signal is applied to said input terminal, the control signal is applied to said control terminal, the second load voltage is applied to said output signal, the output signal with said applied second load voltage is compared with the second-level reference voltage, and a second function test is performed;
wherein either said first step or said second step can be executed first;
and wherein when the first level of the reference voltage is greater than the second level, the first load voltage is greater than the first level of the reference voltage, and the second load voltage is less than the second level of the reference voltage.
